(19) United States
(12) Patent Application Publication
(10) Pub. No.: US 2014/0131725 A1
(43) Pub. Date: May 15, 2014

(54) LIGHT EMITTING DIODE EPITAXY STRUCTURE

(71) Applicant: ADVANCED OPTOELECTRONIC TECHNOLOGY, INC., Hsinchu Hsien (TW)

(72) Inventors: YA-CHI LIEN, Hsinchu (TW); TZU-CHIEN HUNG, Hsinchu (TW)

(73) Assignee: ADVANCED OPTOELECTRONIC TECHNOLOGY, INC., Hsinchu Hsien (TW)

(21) Appl. No.: 13/962,956

(22) Filed: Aug. 9, 2013

(30) Foreign Application Priority Data
Nov. 15, 2012 (CN) 2012104591514

(51) Int. Cl. H01L 33/24; H01L 33/32

(52) U.S. Cl. CPC H01L 33/24; H01L 33/32
USPC 257/76; 257/103

(57) ABSTRACT

A light emitting diode (LED) epitaxy structure includes an N-type semiconductor layer; an active layer arranged on the N-type semiconductor layer, and a P-type semiconductor layer arranged on the active layer. A horizontal cross-sectional area defined by the active layer is a parallelogram, and none of the internal angles of the parallelogram is a right angle.

### BACKGROUND

1. Technical Field

The present disclosure generally relates to solid state light emitting devices and, more particularly, to a light emitting diode (LED) epitaxy structure with high light extraction efficiency.

2. Description of the Related Art

LEDs have many advantages, such as high luminosity, low operational voltage, low power consumption, compatibility with integrated circuits, easy driving, long term reliability, and environmental friendliness, all of which have promoted the wide use of LEDs as a light source.

Referring to FIGS. 3 and 4, an LED epitaxy structure 100 in related art includes an N-type semiconductor layer 20, an active layer 30, and a P-type semiconductor layer 40, which are arranged on a substrate 10 in that sequence. Generally, the LED epitaxy structure has a cuboid shape, and a horizontal cross-sectional area of the active layer 30 is rectangular; therefore, a radiation angle of each of four corners of the active layer 30 is a right angle. Some of the light emitted from the active layer 30 and incident on one side surface of the active layer 30 may have an incident angle larger than a critical angle. In such case, the light may be totally reflected by the one side surface and the other side surfaces of the active layer 30 many times, and be unable to escape from the active layer 30. Thus, the light extraction efficiency of the side surfaces of the LED epitaxy structure is limited.

Therefore, what is needed is an LED epitaxy structure which can overcome the described limitations.

### BRIEF DESCRIPTION OF THE DRAWINGS

FIG. 1 is an isometric view of an LED epitaxy structure, according to an exemplary embodiment of the present disclosure.

FIG. 2 is a horizontal cross section of an active layer of the LED epitaxy structure of FIG. 1, taken along line II-II thereof, and showing essential light pathways.

FIG. 3 is an isometric view of an LED epitaxy structure of related art.

FIG. 4 is a horizontal cross section an active layer of the LED epitaxy structure of FIG. 3, taken along line IV-IV thereof, and showing essential light pathways.

### DETAILED DESCRIPTION OF EMBODIMENTS

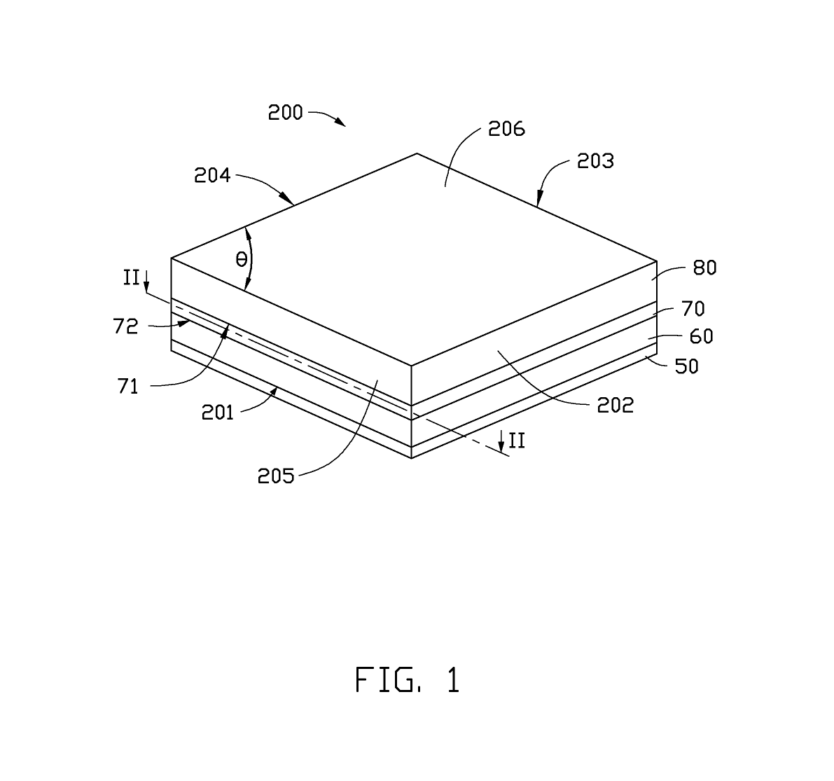

Referring to FIG. 1, an LED epitaxy structure 200, in accordance with an embodiment, is provided. The LED epitaxy structure 200 includes an N-type semiconductor layer 60, an active layer 70, and a P-type semiconductor layer 80, which are arranged on a substrate 50 in that sequence.

In the present embodiment, the N-type semiconductor layer 60 is an n-type gallium nitride (GaN) layer. The P-type semiconductor layer 80 is a p-type GaN layer. The active layer 70 acts as a light emitting surface of the LED epitaxy structure 200.

The LED epitaxy structure 200 includes a bottom surface 201 and a top surface 206 at opposite sides thereof, and four side surfaces 202, 203, 204, 205 located between and connected to the bottom surface 201 and the top surface 206. In the present embodiment, the bottom surface 201 is an undersurface of the N-type semiconductor layer 60 and is adjacent to an upper surface of the substrate 50. The top surface 206 is an upper surface of the P-type semiconductor layer 80. The four side surfaces 202, 203, 204, 205 are perpendicular to the bottom surface 201 and the top surface 206.

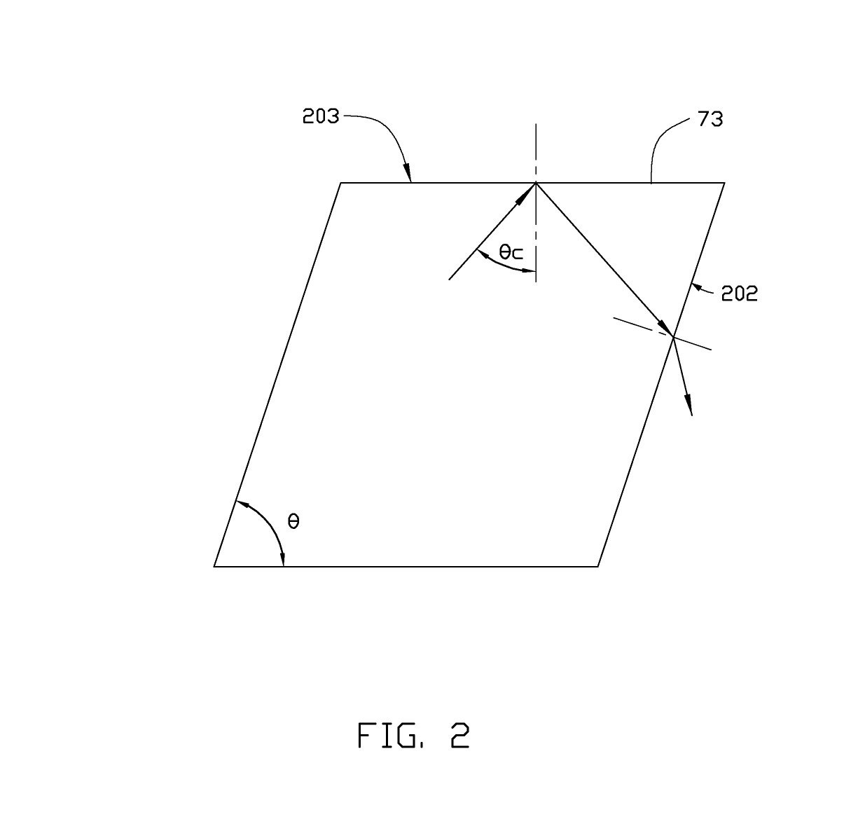

Referring to FIG. 2 also, the active layer 70 includes a first surface 71 connected to the P-type semiconductor layer 80, and a second surface 72 connected to the N-type semiconductor layer 60. In the present embodiment, the first surface 71 and the second surface 72 are parallel to the bottom surface 201 and the top surface 206 of the LED epitaxy structure 200. A horizontal cross-sectional area 73 of the active layer 70 is a parallelogram, wherein none of the inner angles of the parallelogram is a right angle. An internal angle (θ) of the parallelogram is in the range of from greater than or equal to 60 degrees to less than 80 degrees. In the present embodiment, the horizontal cross-sectional area 73 is parallel to the first surface 71 and the second surface 72. The active layer 70 can be GaN or AlₓIn_{y}Ga_{1-x-y}N (0<x<1, 0<y<1).

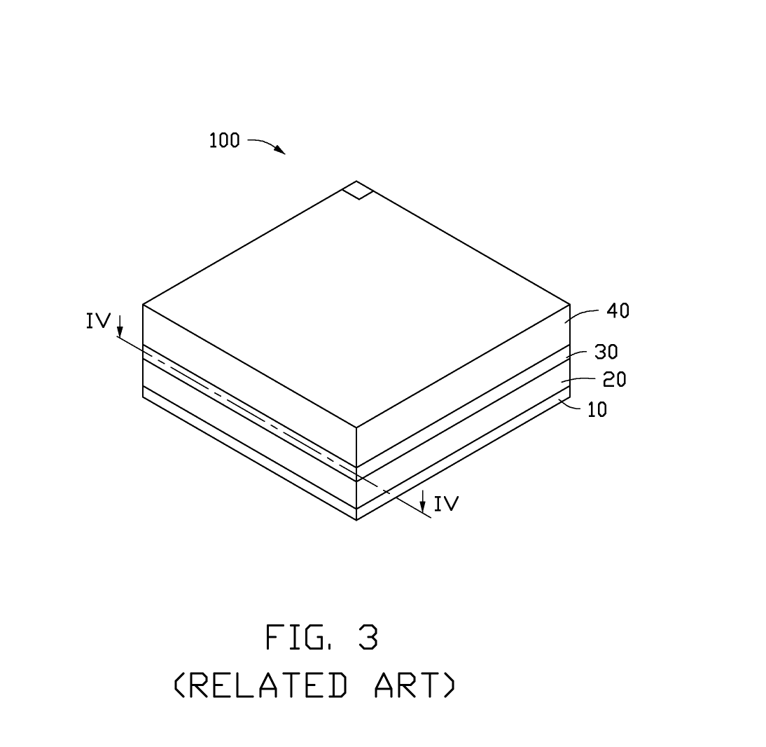

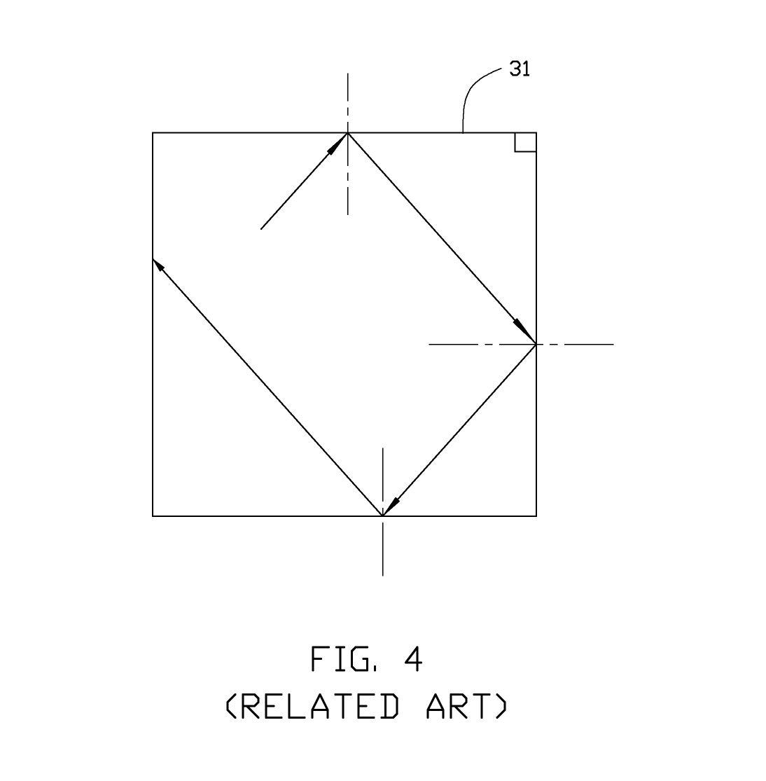

The index of refraction of each of GaN and AlₓIn_{y}Ga_{1-x-y}N is 2.3, and the index of refraction of air is 1. Therefore, light emitted from the active layer 70 and incident to each side surface of the active layer 70 has a critical angle θ_{c} of 25 degrees. When the incident angle of the light is less than or equal to 25 degrees, light emitted from the active layer 70 can totally emit to the ambient air through the side surfaces 202, 203, 204, 205. Referring to the related art LED epitaxy structure 100 shown in FIGS. 3-4, only light with an incident angle in the range from 0 to 25 degrees and in the range from 65 to 90 degrees can escape from the side surfaces of the active layer 30. Light with an incident angle between 25 and 65 degrees is totally reflected between the side surfaces and thus trapped within the active layer 30. In contrast, the LED epitaxy structure 200 uses the acute angles of the parallelogram to regulate incident angles of light, thereby reducing total reflection of the light within the active layer 70. For example, as shown in FIG. 2, if light incident on a second one of the side surfaces 203 of the LED epitaxy structure 200 has an incident angle of 45 degrees, the light is totally reflected by the second side surface 203 towards an adjacent first one of the side surfaces 202 of the LED epitaxy structure 200. Due to the angle between the first and second side surfaces 202, 203 being less than 90 degrees (such as 60 degrees), the light incident on the first side surface 202 has an incident angle of 15 degrees, which is less than the critical angle. Thus, the light incident on the first side surface 202 is not totally reflected and instead escapes out of the LED epitaxy structure 200.

In summary, the horizontal cross-sectional area 73 of the active layer 70 is a parallelogram, wherein none of the inner angles of the parallelogram is a right angle. Therefore, more light can travel out of the active layer 70 to the outside of the LED epitaxy structure 200 for lighting. That is, the light extraction efficiency of the side surfaces 202, 203, 204, 205 of the LED epitaxy structure 200 can be improved.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) epitaxy structure comprising:
an N-type semiconductor layer;
an active layer arranged on the N-type semiconductor layer, a horizontal cross-sectional area defined by the active layer being a parallelogram, wherein none of the internal angles of the parallelogram is a right angle; and
a P-type semiconductor layer arranged on the active layer.

2. The LED epitaxy structure of claim 1, wherein the active layer is one of gallium nitride (GaN) and AlₓIn_{y}Ga_{1-x-y}N, wherein 0<x<1 and 0<y<1.

3. The LED epitaxy structure of claim 1, wherein each of two diagonally opposite internal angles of the cross-sectional area of the active layer is larger than or equal to 65 degrees and less than 90 degrees.

4. The LED epitaxy structure of claim 1, wherein each of two diagonally opposite internal angles of the cross-sectional area of the active layer is larger than or equal to 65 degrees and less than 80 degrees.

5. The LED epitaxy structure of claim 1, further comprising a bottom surface, a top surface opposite to the bottom surface, and four side surfaces located between and connected to the bottom surface and the top surface, wherein the four side surfaces are substantially perpendicular to the bottom surface and the top surface

6. The LED epitaxy structure of claim 5, wherein the active layer comprises a first surface connected to the P-type semiconductor layer and a second surface connected to the N-type semiconductor layer, the first and second surfaces being parallel to the top surface and the bottom surface.

7. The LED epitaxy structure of claim 6, wherein the cross-sectional area is parallel to the first surface and the second surface.

8. The LED epitaxy structure of claim 1, wherein the N-type semiconductor layer is an n-type gallium nitride (GaN) layer.

9. The LED epitaxy structure of claim 1, wherein the P-type semiconductor layer is a p-type gallium nitride (GaN) layer.

10. A light emitting diode (LED) epitaxy structure comprising:
an N-type semiconductor layer;
an active layer arranged on the N-type semiconductor layer; and
a P-type semiconductor layer arranged on the active layer;
wherein the LED epitaxy structure comprises a top surface, a bottom surface opposite to and parallel to the top surface, and four side surfaces connected to the top surface and the bottom surface, the active layer defines a cross-sectional area in the shape of a parallelogram parallel to the top surface, and none of the internal angles of the parallelogram is a right angle.

11. The LED epitaxy structure of claim 10, wherein the four side surfaces are substantially perpendicular to the top surface and the bottom surface.

12. The LED epitaxy structure of claim 10, wherein each of two diagonally opposite internal angles of the cross-sectional area of the active layer is larger than or equal to 65 degrees and less than 90 degrees.

13. The LED epitaxy structure of claim 10, wherein each of two diagonally opposite internal angles of the cross-sectional area of the active layer is larger than or equal to 65 degrees and less than 80 degrees.

14. The LED epitaxy structure of claim 10, wherein active layer is one of gallium nitride (GaN) and AlₓIn_{y}Ga_{1-x-y}N, wherein 0<x<1 and 0<y<1.
